(19) United States
(12) Patent Application Publication
(10) Pub. No.: US 2026/0213513 A1
(43) Pub. Date: Jul. 23, 2026

(54) ELECTRICAL CONNECTION UNIT AND METAL COMPONENT

(71) Applicant: Yazaki Corporation, Tokyo (JP)

(72) Inventors: Kazuhiko TSUCHIYA, Kakegawa-shi (JP); Hirotaka MUKASA, Kakegawa-shi (JP); Ryu SENOO, Kakegawa-shi (JP); Hirokuni KURASHIKI, Susono-shi (JP)

(73) Assignee: Yazaki Corporation, Tokyo (JP)

(21) Appl. No.: 19/571,727

(22) Filed: Mar. 19, 2026

Related U.S. Application Data
(63) Continuation of application No. PCT/JP2025/007412, filed on Mar. 3, 2025.

(30) Foreign Application Priority Data
Apr. 8, 2024 (JP) 2024-062215

(51) Int. Cl. H02G 3/16; H02B 1/20; H02G 3/03

(52) U.S. Cl. CPC H02G 3/16; H02B 1/20; H02G 3/03

(57) ABSTRACT

An electrical connection unit includes a first bus bar and a metal component. At least a part of the first bus bar has a plate shape. The metal component is disposed between the first bus bar and a connection target component that is an electronic component or a second bus bar. The metal component electrically connects the first bus bar and the connection target component. At least a part of the metal component has a thickness larger than a plate thickness of the first bus bar.

### CROSS-REFERENCE TO RELATED APPLICATION

This application is a continuation application of International Application No. PCT/JP2025/007412 filed on March 3, 2025 which claims the benefit of priority from Japanese Patent Application No. 2024-062215 filed on April 8, 2024 and designating the U.S., the entire contents of which are incorporated herein by reference.

### TECHNICAL FIELD

Embodiments of the present invention relate to an electrical connection unit and a metal component.

Priority is claimed on Japanese Patent Application No. 2024-062215, filed April 8, 2024, the content of which is incorporated herein by reference.

### BACKGROUND ART

As one of in-vehicle devices, an electrical connection unit including an electronic component and a bus bar connected to the electronic component is used.

### CITATION LIST

### Patent Document

### Patent Document 1

PCT International Publication No. WO 2021/059767

### Patent Document 2

Japanese Unexamined Patent Application, First Publication No. 2018-093711

### SUMMARY OF INVENTION

### Technical Problem

As the current of the electrical connection unit increases, the amount of heat generation of the electronic component tends to increase.

One embodiment provides an electrical connection unit and a metal component that can improve thermal characteristics.

### Solution to Problem

An electrical connection unit of one embodiment includes a first bus bar and a metal component. At least a part of the first bus bar has a plate shape. The metal component is disposed between the first bus bar and a connection target component that is an electronic component or a second bus bar. The metal component electrically connects the first bus bar and the connection target component. At least a part of the metal component has a thickness larger than a plate thickness of the first bus bar.

The metal component of one embodiment is disposed between the first bus bar and a connection target component that is an electronic component or a second bus bar. The metal component electrically connects the first bus bar and the connection target component. At least a part of the metal component has a thickness larger than a plate thickness of the first bus bar.

### Advantageous Effects of Invention

According to one embodiment, the thermal characteristics of the electrical connection unit can be improved.

### BRIEF DESCRIPTION OF DRAWINGS

FIG. 1 is a cross-sectional view illustrating an electrical connection unit of a first embodiment.

FIG. 2 is a perspective view illustrating a part of the electrical connection unit of the first embodiment.

FIG. 3 is an exploded perspective view illustrating a part of the electrical connection unit of the first embodiment.

FIG. 4 is a plan view illustrating a first electronic component and a metal component of the first embodiment.

FIG. 5 is a cross-sectional view for describing a method for manufacturing the electrical connection unit of the first embodiment.

FIG. 6 is a cross-sectional view for describing the method for manufacturing the electrical connection unit of the first embodiment.

FIG. 7 is a cross-sectional view for describing the method for manufacturing the electrical connection unit of the first embodiment.

FIG. 8 is a cross-sectional view for describing an operation of the electrical connection unit of the first embodiment.

FIG. 9 is a cross-sectional view illustrating an electrical connection unit according to a first modified example of the first embodiment.

FIG. 10 is a cross-sectional view illustrating an electrical connection unit according to a second modified example of the first embodiment.

FIG. 11 is a cross-sectional view illustrating an electrical connection unit according to a third modified example of the first embodiment.

FIG. 12 is a perspective view illustrating a part of the electrical connection unit according to the third modified example of the first embodiment.

FIG. 13 is a cross-sectional view illustrating a part of an electrical connection unit of a second embodiment.

FIG. 14 is a perspective view illustrating a part of the electrical connection unit of the second embodiment.

FIG. 15 is a cross-sectional view for describing a method for manufacturing the electrical connection unit of the second embodiment.

FIG. 16 is a cross-sectional view for describing the method for manufacturing the electrical connection unit of the second embodiment.

FIG. 17 is a perspective view illustrating a part of an electrical connection unit of a third embodiment.

### DESCRIPTION OF EMBODIMENTS

Hereinafter, an embodiment will be described with reference to the drawings. In the following description, components having the same or similar functions are denoted by the same reference numbers. Redundant descriptions of these components may be omitted. In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. “Parallel”, “orthogonal”, or “the same” may include “substantially parallel”, “substantially orthogonal”, or “substantially the same”, respectively.

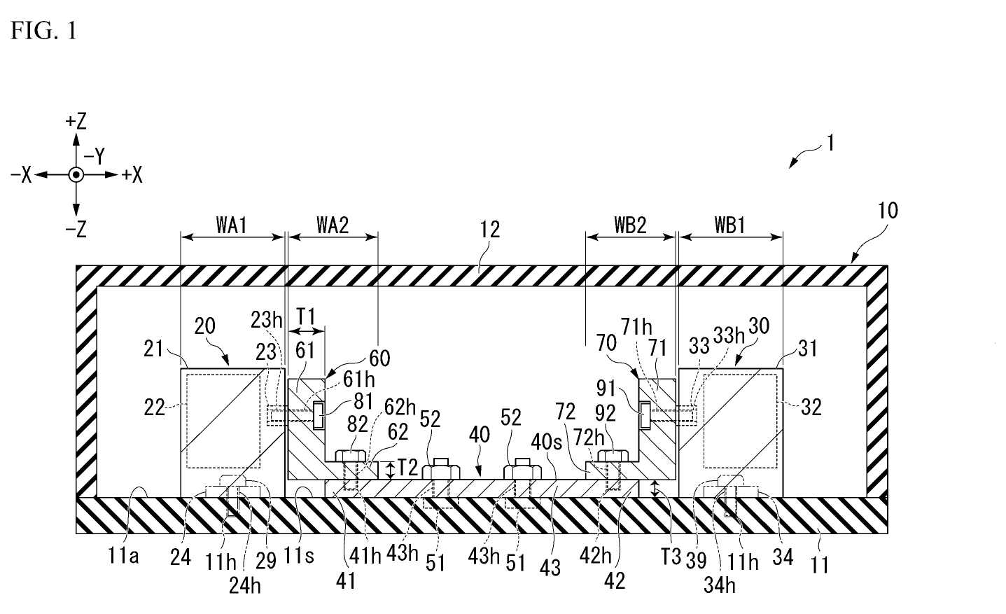

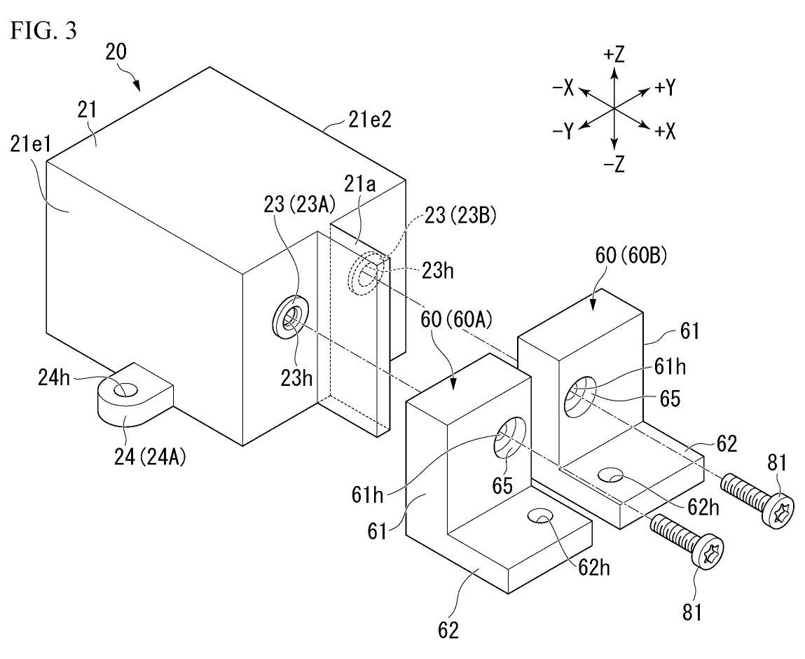

In the present disclosure, a +X direction, a -X direction, a +Y direction, a -Y direction, a +Z direction, and a -Z direction are defined as follows. The +X direction is a direction from a first electronic component 20 to be described later toward a first metal component 60 (see FIG. 1). The -X direction is a direction opposite to the +X direction. Hereinafter, the +X direction and the -X direction are simply referred to as an “X direction” when they are not distinguished from each other. The +Y direction is a direction from a first terminal portion 23A toward a second terminal portion 23B of the first electronic component 20 (see FIG. 3). The -Y direction is a direction opposite to the +Y direction. Hereinafter, the +Y direction and the -Y direction are simply referred to as a “Y direction” when they are not distinguished from each other. The +Z direction is a direction from a base member 11 to be described later toward a bus bar 40 (see FIG. 1). The -Z direction is a direction opposite to the +Z direction. Hereinafter, in a case where the +Z direction and the -Z direction are not distinguished, the directions will be simply referred to as the “Z direction”.

### First Embodiment

First, a first embodiment will be described. In the first embodiment, the X direction is an example of a “first direction”. The Z direction is an example of a “second direction”.

### A1. Constitution of Electrical Connection Unit

FIG. 1 is a cross-sectional view illustrating an electrical connection unit 1 according to the first embodiment. The electrical connection unit 1 is used for a vehicle such as an electric vehicle (EV), a hybrid electric vehicle (HEV), or a plug-in hybrid electric vehicle (PHEV), for example. The electrical connection unit 1 is, for example, a component called an electrical connection box or a junction box.

FIG. 1 is a cross-sectional view illustrating the electrical connection unit 1. The electrical connection unit 1 includes, for example, a housing 10, a plurality of electronic components 20 and 30, a plurality of bus bars 40 (only one is illustrated in FIG. 1), and a plurality of metal components 60 and 70.

### A1.1 Housing

The housing 10 is an outer member that forms the outer shape of the electrical connection unit 1. The housing 10 accommodates the plurality of electronic components 20 and 30, the plurality of bus bars 40, and the plurality of metal components 60 and 70. The housing 10 includes, for example, a base member 11 and a cover member 12.

The base member 11 is, for example, a member that forms a bottom portion of the housing 10. The base member 11 is made of, for example, a synthetic resin and has insulating properties. The base member 11 has a support surface 11a exposed to the inside of the housing 10. At least a part of the support surface 11a has, for example, a plane 11s in the X direction and the Y direction.

In the present embodiment, a plurality of fastening members 51 (for example, screws) are fixed to the base member 11. For example, the fastening member 51 is fixed to the base member 11 by being insert-molded into the base member 11. For example, the head portion of the fastening member 51 is embedded in the base member 11. The shaft portion of the fastening member 51 protrudes in the +Z direction from the plane 11s of the base member 11 and extends in the +Z direction. The shaft portion of the fastening member 51 has a screw. The fastening member 51 may be fixed to the base member 11 by means different from insert molding. In the present embodiment, a plurality of bus bars 40 to be described later is fixed to the base member 11. The base member 11 is an example of a “support”.

The cover member 12 is, for example, a member that forms a lid portion of the housing 10. In the present embodiment, the housing 10 is formed by combining the base member 11 and the cover member 12. The cover member 12 is made of, for example, a synthetic resin and has insulating properties. The bus bar 40 may be fixed to the cover member 12 instead of the base member 11. The cover member 12 is another example of the “support”.

### A1.2 Electronic Component

The plurality of electronic components 20 and 30 are electronic components mounted according to functions or applications required for the electrical connection unit 1. Each of the electronic components 20 and 30 is, for example, a connector, a fuse, a relay (for example, a mechanical relay or a semiconductor relay), a capacitor, a branch component, an electronic control unit, or an electronic component unit in which two or more of these are unitized. Note that the types of the electronic components 20 and 30 are not limited to the above examples. The electronic component 20 and the electronic component 30 may be the same type of components or different types of components. The electronic components 20 and 30 are, for example, heat generating components that generate heat at the time of energization.

Hereinafter, for convenience of description, the electronic component 20 may be referred to as a “first electronic component 20”. Further, the electronic component 30 may be referred to as a “second electronic component 30”. Note that the electrical connection unit 1 may include only one electronic component (for example, only one of the electronic components 20 and 30) instead of including the plurality of electronic components 20 and 30. The first electronic component 20 is an example of a “connection target component”. The second electronic component 30 is another example of a “connection target component”.

### A1.2.1 First Electronic Component

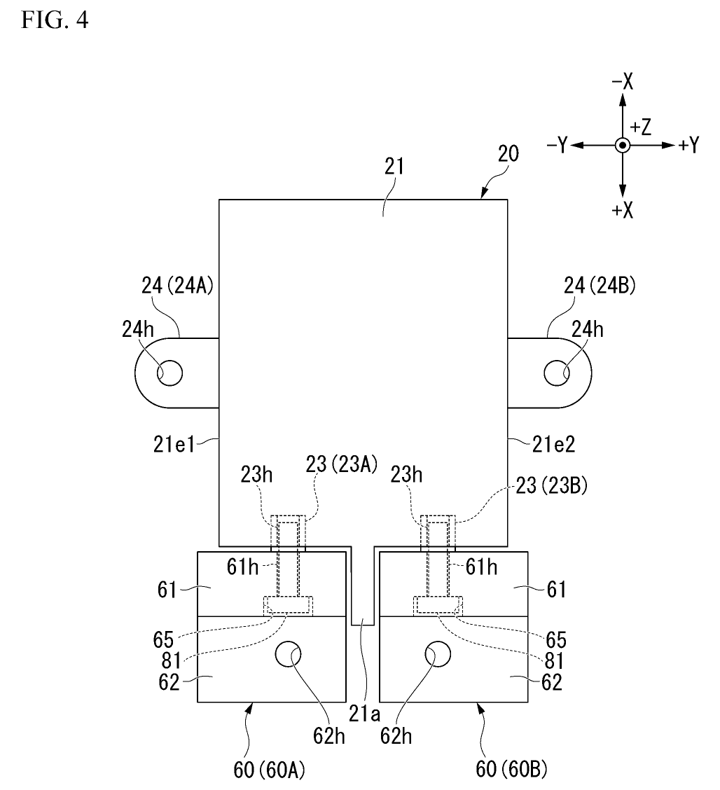

The first electronic component 20 includes, for example, a case 21, a body portion 22, a plurality of terminal portions 23 (see FIG. 3), and a plurality of attachment portions 24 (see FIG. 4).

### Case

The case 21 is an outer member that forms most of the outer shape of the first electronic component 20. The case 21 is made of, for example, a synthetic resin and has insulating properties. The case 21 accommodates the body portion 22. The case 21 and the body portion 22 may be integrally formed.

### Body Portion

The body portion 22 is a portion that performs a main function of the first electronic component 20. For example, in a case where the first electronic component 20 is a relay, the body portion 22 includes a switch (for example, a contact) that switches between a conductive state and a non-conductive state. For example, in a case where the first electronic component 20 is a fuse, the body portion 22 includes a fusible portion that melts when an overcurrent flows. For example, in a case where the first electronic component 20 is a capacitor, the body portion 22 includes a portion that stores electric charge.

### Terminal Portion

The terminal portion 23 is an electrical connection portion exposed to the outside of the case 21. The terminal portion 23 is electrically connected to the body portion 22 inside the case 21. In the present embodiment, the first electronic component 20 includes a first terminal portion 23A and a second terminal portion 23B as the plurality of terminal portions 23 (see FIG. 3). One of the first terminal portion 23A and the second terminal portion 23B is a terminal portion on the positive electrode side. The other of the first terminal portion 23A and the second terminal portion 23B is a terminal portion on the negative electrode side. The terminal portion 23 is disposed at a position away from the support surface 11a of the base member 11.

In the present embodiment, the first terminal portion 23A and the second terminal portion 23B are provided at end portions on the +X direction side of the first electronic component 20. The first terminal portion 23A and the second terminal portion 23B are arranged side by side in the Y direction (see FIG. 3). Hereinafter, when the first terminal portion 23A and the second terminal portion 23B are not distinguished, they are simply referred to as “terminal portions 23”. The terminal portion 23 has an attachment hole 23h to which a first fastening member 81 (for example, a screw) described later is attached. The attachment hole 23h is open in the X direction. For example, the attachment hole 23h has a screw groove on the inner peripheral surface. The terminal portion 23 may be referred to as a “fastening portion”.

### Attachment Portion

The attachment portion 24 is a portion for fixing the first electronic component 20. For example, the attachment portion 24 is a portion for fixing the first electronic component 20 to the base member 11. In the present embodiment, the first electronic component 20 includes, as the plurality of attachment portions 24, a first attachment portion 24A and a second attachment portion 24B (see FIG. 4). The first attachment portion 24A and the second attachment portion 24B are separately disposed on both sides of the case 21 in the Y direction. For example, the first attachment portion 24A protrudes from the case 21 in the -Y direction. The second attachment portion 24B protrudes from the case 21 in the +Y direction.

Hereinafter, when the first attachment portion 24A and the second attachment portion 24B are not distinguished from each other, they are simply referred to as “attachment portions 24”. The attachment portion 24 has an attachment hole 24h to which the fastening member 29 (for example, a screw) is attached. The attachment hole 24h is open in the Z direction. The attachment hole 24h is an insertion hole through which the fastening member 29 passes. In the present embodiment, the base member 11 has an attachment hole 11h at a position corresponding to the attachment hole 24h. The attachment hole 11h is open in the Z direction. For example, the attachment hole 11h has a screw groove on the inner peripheral surface. In the present embodiment, the fastening member 29 passed through the attachment hole 24h of the attachment portion 24 is engaged with the attachment hole 11h, thereby fixing the first electronic component 20 to the base member 11. The attachment hole 11h may be an attachment hole directly provided in the base member 11, or may be an attachment hole of an engagement member (for example, a nut) embedded in the base member 11 by, for example, insert molding or other means.

### A1.2.2 Second Electronic Component

The second electronic component 30 includes, for example, a case 31, a body portion 32, a plurality of terminal portions 33, and a plurality of attachment portions 34. Details of the second electronic component 30 are, for example, similar to those of the first electronic component 20. Therefore, in the description regarding the second electronic component 30, “first electronic component 20”, “case 21”, “body portion 22”, “terminal portion 23”, “attachment hole 23h”, “attachment portion 24”, “attachment hole 24h”, “fastening member 29”, and “+X direction” in the description regarding the first electronic component 20 described above may be replaced with “second electronic component 30”, “case 31”, “body portion 32”, “terminal portion 33”, “attachment hole 33h”, “attachment portion 34”, “attachment hole 34h”, “fastening member 39”, and “-X direction”, respectively.

### A1.3 Bus Bar

The bus bar 40 is a connection member included in the electrical connection unit 1. The bus bar 40 is, for example, a connection member that electrically connects a plurality of electronic components. Alternatively, the bus bar 40 may be a connection member that connects one electronic component and the outside of the electrical connection unit 1.

At least a part of the bus bar 40 has a plate shape. In the present embodiment, the bus bar 40 has a plate shape over the entire bus bar 40. The bus bar 40 is disposed along the base member 11. The bus bar 40 has a planar plate surface 40s. The plate surface 40s of the bus bar 40 is parallel to the plane 11s of the base member 11 over the entire length of the bus bar 40. The bus bar 40 is fixed to the base member 11, for example. The bus bar 40 has a plate thickness T3. The plate thickness T3 is the thickness of the bus bar 40 in the Z direction. The bus bar 40 is an example of a “first bus bar”.

Here, an example of the bus bar 40 will be described in detail by taking up the bus bar 40 that electrically connects the first electronic component 20 and the second electronic component 30. The bus bar 40 includes, for example, a first connection portion 41, a second connection portion 42, and an extending portion 43. In the present embodiment, each of the first connection portion 41, the second connection portion 42, and the extending portion 43 has a plate shape in the X direction and the Y direction.

### First Connection Portion

The first connection portion 41 is a portion electrically connected to the first electronic component 20. The first connection portion 41 is provided at one end portion of the bus bar 40. The first connection portion 41 has an attachment hole 41h through which the second fastening member 82 (for example, a screw) passes. The attachment hole 41h is open in the Z direction. In the present embodiment, the first connection portion 41 is disposed away from the terminal portion 23 of the first electronic component 20. For example, the first connection portion 41 is disposed along the base member 11.

### Second Connection Portion

The second connection portion 42 is a portion electrically connected to the second electronic component 30. The second connection portion 42 is provided at the other end portion of the bus bar 40. The second connection portion 42 has an attachment hole 42h through which the fastening member 92 (for example, a screw) passes. The attachment hole 42h is open in the Z direction. In the present embodiment, the second connection portion 42 is disposed away from the terminal portion 33 of the second electronic component 30. For example, the second connection portion 42 is disposed along the base member 11.

### Extending portion

The extending portion 43 is provided between the first connection portion 41 and the second connection portion 42. The extending portion 43 extends, for example, in the X direction along the base member 11, and connects the first connection portion 41 and the second connection portion 42. In the present embodiment, the extending portion 43 has an attachment hole 43h through which the fastening member 51 passes. The bus bar 40 is placed on the plane 11s of the base member 11 in a state where the shaft portion of the fastening member 51 passes through the attachment hole 43h. In a state where the shaft portion of the fastening member 51 passes through the attachment hole 43h, an engagement member 52 (for example, a nut) is attached to the shaft portion of the fastening member 51 from the +Z direction side, so that the bus bar 40 is fixed to the base member 11.

### A1.4 Metal Component

The plurality of metal components 60 and 70 are heat storage members (heat absorbing members) that increase the heat capacity of the energization path of the electrical connection unit 1. The plurality of metal components 60 and 70 store (absorb) at least some of heat generated by the electronic components 20 and 30, for example. Alternatively/additionally, the plurality of metal components 60 and 70 may store (absorb) at least some of heat generated by the bus bar 40 due to energization. Each of the metal components 60 and 70 may be referred to as a “heat storage component” or a “heat absorbing component”.

Hereinafter, for convenience of description, the metal component 60 may be referred to as a “first metal component 60”. In addition, the metal component 70 may be referred to as a “second metal component 70”. Note that the electrical connection unit 1 may include only one metal component (for example, only one of the metal components 60 and 70) instead of including the plurality of metal components 60 and 70.

### A1.4.1 First Metal Component

The first metal component 60 is disposed between the first electronic component 20 and the bus bar 40. In the present disclosure, the phrase “the metal component is disposed between the electronic component and the bus bar” is not limited to a case where a part of the metal component is located between the electronic component and the bus bar when viewed in the X direction or the Y direction. The phrase “the metal component is disposed between the electronic component and the bus bar” may correspond to a case where a part of the metal component is located between the electronic component and the bus bar when viewed in a direction inclined with respect to the X direction or the Y direction. The first metal component 60 electrically connects the terminal portion 23 of the first electronic component 20 and the first connection portion 41 of the bus bar 40. The first metal component 60 includes, for example, a first portion 61 and a second portion 62.

### First Portion

The first portion 61 is a portion connected to the terminal portion 23 of the first electronic component 20. The first portion 61 is a relatively thick plate portion in the Y direction and the Z direction. The first portion 61 extends in the Z direction along an end portion on the +X direction side of the first electronic component 20. The first portion 61 is in a posture standing with respect to the support surface 11a (for example, the plane 11s) of the base member 11.

The first portion 61 is adjacent to the first electronic component 20 in the X direction. For example, the first portion 61 is adjacent to at least a part of the body portion 22 of the first electronic component 20 in the X direction. The first portion 61 faces the terminal portion 23 of the first electronic component 20 from the +X direction side. The first portion 61 is connected to the terminal portion 23 of the first electronic component 20 in the X direction.

In the present embodiment, the first portion 61 has a first attachment hole 61h through which the first fastening member 81 (for example, a screw) passes. The first attachment hole 61h is open in the X direction. The first portion 61 has a recess 65 on the +X direction side of the first attachment hole 61h. The recess 65 is an accommodation portion that accommodates a head portion of the first fastening member 81 inserted into the first attachment hole 61h. The first fastening member 81 passed through the first attachment hole 61h is engaged with the attachment hole 23h of the terminal portion 23 of the first electronic component 20, thereby physically and electrically connecting the first portion 61 to the terminal portion 23 of the first electronic component 20.

### Second Portion

The second portion 62 is a portion connected to the first connection portion 41 of the bus bar 40. The second portion 62 protrudes in the +X direction from an end portion of the first portion 61 on the -Z direction side. The second portion 62 is a plate portion in the X direction and the Y direction. The second portion 62 extends in the X direction along the first connection portion 41 of the bus bar 40. In the present embodiment, the first portion 61 and the second portion 62 form one L-shaped piece of the first metal component 60.

The second portion 62 is adjacent to the first connection portion 41 of the bus bar 40 in the Z direction. The first portion 61 faces the first connection portion 41 of the bus bar 40 from the +Z direction side. The second portion 62 is connected to the first connection portion 41 of the bus bar 40 in the Z direction.

In the present embodiment, the second portion 62 has a second attachment hole 62h through which the second fastening member 82 (for example, a screw) passes. The second attachment hole 62h is open in the Z direction. The second fastening member 82 passed through the second attachment hole 62h is engaged with the attachment hole 41h of the first connection portion 41 of the bus bar 40, thereby physically and electrically connecting the second portion 62 to the first connection portion 41 of the bus bar 40.

### Shape of First Metal Component

In the present embodiment, a thickness of at least a part of the first metal component 60 is larger than a plate thickness T3 of the bus bar 40. For example, a thickness T1 of at least a part of the first metal component 60 in the X direction is larger than the plate thickness T3 of the bus bar 40. In the present embodiment, the thickness T1 of the first portion 61 of the first metal component 60 in the X direction is larger than the plate thickness T3 of the bus bar 40. In the present embodiment, the first portion 61 has a thickness T1 larger than the plate thickness T3 of the bus bar 40 as the thickness in the X direction over the entire width of the first portion 61 in the Z direction. From another viewpoint, a thickness T2 of the second portion 62 of the first metal component 60 in the Z direction may be larger than the plate thickness T3 of the bus bar 40.

In the present embodiment, the thickness T1 of the first portion 61 of the first metal component 60 in the X direction is larger than the thickness T2 of the second portion 62 of the first metal component 60 in the Z direction. In the present embodiment, the first portion 61 has the thickness T1 larger than the thickness T2 of the second portion 62 over the entire width of the first portion 61 in the Z direction.

In the present embodiment, the longitudinal direction of the first electronic component 20 is the X direction. The width WA2 of the first metal component 60 in the X direction is, for example, smaller than the width WA1 of the first electronic component 20 in the X direction. When the longitudinal direction of the first electronic component 20 is the Y direction, the width of the first metal component 60 in the Y direction is smaller than the width of the first electronic component 20 in the Y direction, for example.

### Arrangement Example of First Metal Component

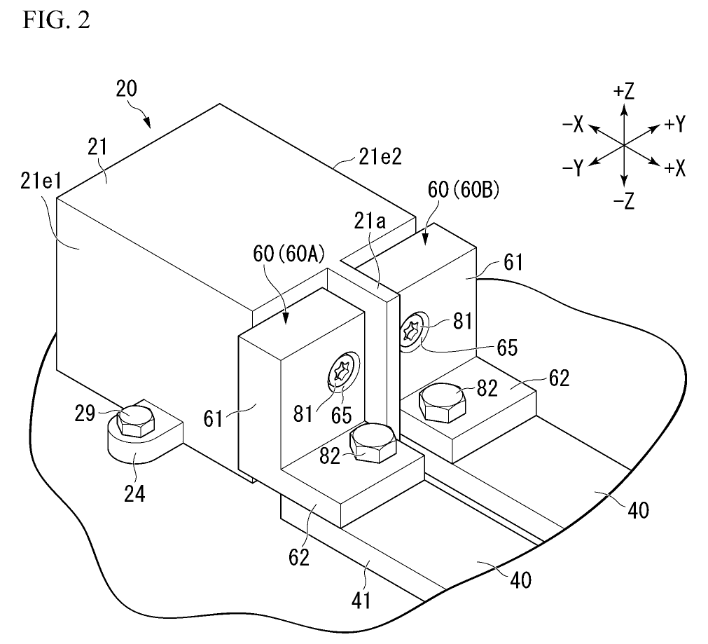

FIG. 2 is a perspective view illustrating a part of the electrical connection unit 1. FIG. 3 is an exploded perspective view of a part of the electrical connection unit 1. In the present embodiment, the electrical connection unit 1 includes a metal component 60A and a metal component 60B as the plurality of first metal components 60. The metal component 60A and the metal component 60B have, for example, the same shape.

The metal component 60A is disposed corresponding to a half portion of the first electronic component 20 on the -Y direction side. The metal component 60A is adjacent to the terminal portion 23A of the first electronic component 20 in the X direction, and is connected to the terminal portion 23A of the first electronic component 20 in the X direction. On the other hand, the metal component 60B is disposed corresponding to a half portion of the first electronic component 20 on the +Y direction side. The metal component 60B is adjacent to the terminal portion 23B of the first electronic component 20 in the X direction, and is connected to the terminal portion 23B of the first electronic component 20 in the X direction.

In the present embodiment, the case 21 has an insulating wall 21a protruding in the +X direction (see FIG. 2). The insulating wall 21a is provided at the center of the case 21 in the Y direction. The insulating wall 21a extends in the X direction and the Y direction. For example, the insulating wall 21a extends over the entire height of the case 21 in the Z direction. The insulating wall 21a is disposed between the first terminal portion 23A and the second terminal portion 23B. The insulating wall 21a electrically insulates the first terminal portion 23A from the second terminal portion 23B. In the present embodiment, the insulating wall 21a is disposed between the first portion 61 of the metal component 60A and the first portion 61 of the metal component 60B. The insulating wall 21a electrically insulates the first portion 61 of the metal component 60A from the first portion 61 of the metal component 60B.

FIG. 4 is a plan view illustrating the first electronic component 20 and the metal components 60A and 60B. In the present embodiment, the case 21 of the first electronic component 20 has an end 21e1 in the -Y direction and an end 21e2 in the +Y direction.

A part of the metal component 60A protrudes toward the -Y direction side from the end 21e1 of the case 21 of the first electronic component 20. A part of the metal component 60A protrudes to a region not overlapping the first electronic component 20 when viewed in the X direction. As a result, the heat capacity of the metal component 60A is increased.

Similarly, a part of the metal component 60B protrudes toward the +Y direction side from the end 21e2 of the case 21 of the first electronic component 20. A part of the metal component 60B protrudes to a region not overlapping the first electronic component 20 when viewed in the X direction. As a result, the heat capacity of the metal component 60B is increased.

### A1.4.2 Second Metal Component

Next, referring back to FIG. 1, the second metal component 70 will be described. The second metal component 70 is disposed between the second electronic component 30 and the bus bar 40. The second metal component 70 electrically connects the terminal portion 33 of the second electronic component 30 and the second connection portion 42 of the bus bar 40. The second metal component 70 includes, for example, a first portion 71 and a second portion 72.

Details of the second metal component 70 are, for example, similar to those of the first metal component 60. Therefore, in the description regarding the second metal component 70, “first portion 61”, “first attachment hole 61h”, “second portion 62”, “second attachment hole 62h”, “first electronic component 20”, “body portion 22”, “terminal portion 23”, “attachment hole 23h”, “first fastening member 81”, “second fastening member 82”, “first connection portion 41”, “attachment hole 41h”, and “+X direction” in the description regarding the first metal component 60 described above may be replaced with “first portion 71”, “first attachment hole 71h”, “second portion 72”, “second attachment hole 72h”, “second electronic component 30”, “body portion 32”, “terminal portion 33”, “attachment hole 33h”, “first fastening member 91”, “second fastening member 92”, “second connection portion 42”, “attachment hole 42h”, and “-X direction”, respectively.

In the present embodiment, the longitudinal direction of the second electronic component 30 is the X direction. The width WB2 of the second metal component 70 in the X direction is, for example, smaller than the width WB1 of the second electronic component 30 in the X direction. When the longitudinal direction of the second electronic component 30 is the Y direction, the width of the second metal component 70 in the Y direction is, for example, smaller than the width of the second electronic component 30 in the Y direction.

### A2. Method for Manufacturing Electrical Connection Unit

Next, a method for manufacturing the electrical connection unit 1 will be described.

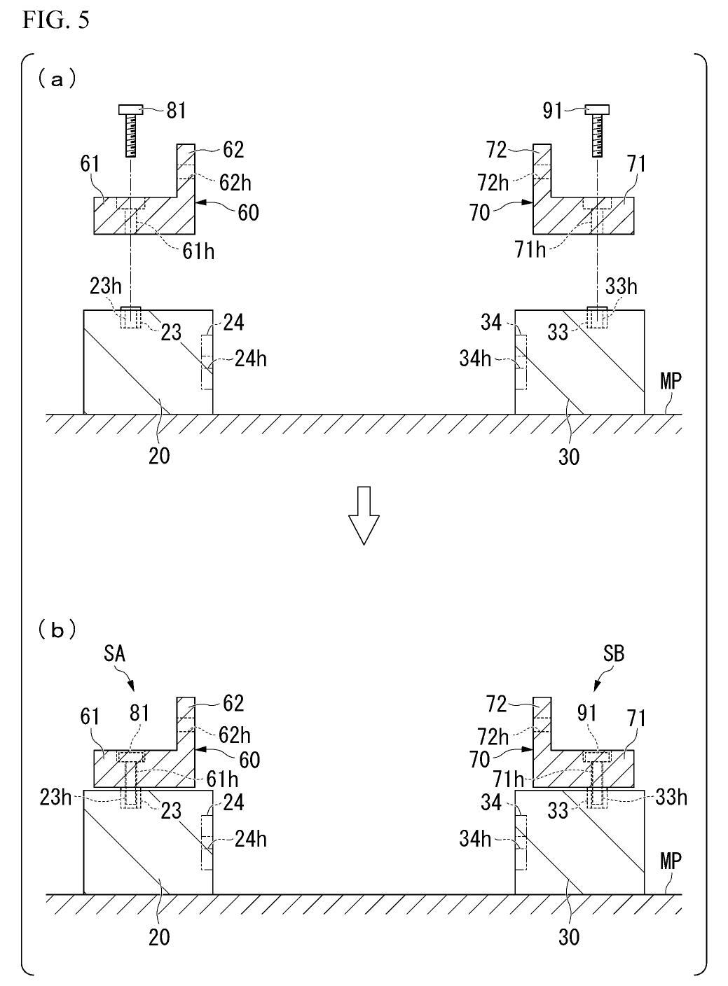

FIGS. 5 to 7 are cross-sectional views for describing the method for manufacturing the electrical connection unit 1.

### First Step

FIG. 5 illustrates a first step. In the first step, the first metal component 60 is fixed to the terminal portion 23 of the first electronic component 20 using the fastening member 81. As a result, a first assembly SA in which the first electronic component 20 and the first metal component 60 are integrated is formed.

The first step is performed, for example, as follows. First, the first electronic component 20 is placed on a placement table MP in a posture in which the attachment hole 23h of the terminal portion 23 of the first electronic component 20 is directed in a vertical direction. Next, the first metal component 60 is placed on the first electronic component 20 in a posture in which the first attachment hole 61h of the first metal component 60 is directed in the vertical direction. The first attachment hole 61h of the first metal component 60 and the attachment hole 23h of the terminal portion 23 of the first electronic component 20 are aligned. The first step is performed in a state where the first electronic component 20 and the first metal component 60 are in a first posture. The first posture is a posture in which the attachment hole 23h and the first attachment hole 61h are directed in the vertical direction.

Next, the fastening member 81 is inserted into the first attachment hole 61h of the first metal component 60 in the vertical direction. The fastening member 81 passed through the attachment hole 61h of the first metal component 60 is engaged with the attachment hole 23h of the terminal portion 23 of the first electronic component 20. As a result, a first assembly SA in which the first electronic component 20 and the first metal component 60 are integrated is formed. The vertical direction is an example of a “first attachment direction”.

Similarly, the second metal component 70 is fixed to the terminal portion 33 of the second electronic component 30 using the fastening member 91. As a result, a second assembly SB in which the second electronic component 30 and the second metal component 70 are integrated is formed.

### Second Step

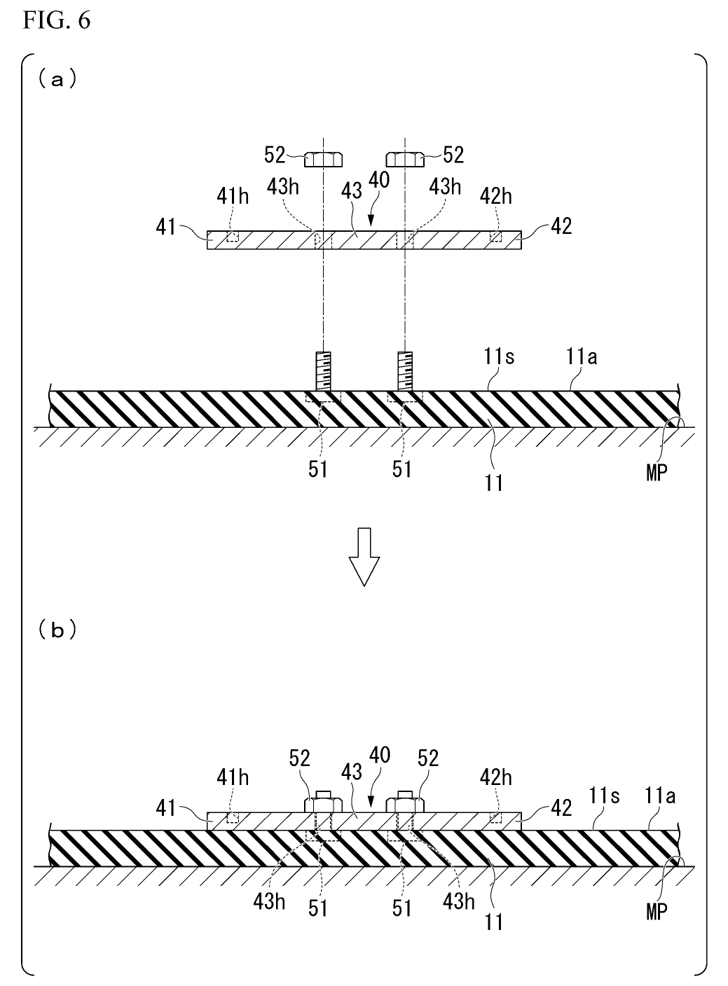

FIG. 6 illustrates a second step. In the second step, the bus bar 40 is fixed to the base member 11. This step may be performed before the first step, after the first step, or in parallel with the first step.

The second step is performed, for example, as follows. As described above, the fastening member 51 is previously fixed to the base member 11, for example. The fastening member 51 protrudes in the vertical direction. The bus bar 40 is placed on the base member 11 such that the fastening member 51 is inserted into the attachment hole 43h of the bus bar 40 in the vertical direction. Next, the engagement member 52 (for example, a nut) is engaged with the upper end portion of the fastening member 51 in the vertical direction. As a result, the bus bar 40 is fixed to the base member 11. In the present embodiment, the bus bar 40 is fixed to the base member 11 before fixing the electronic components 20 and 30 to the base member 11.

### Third Step

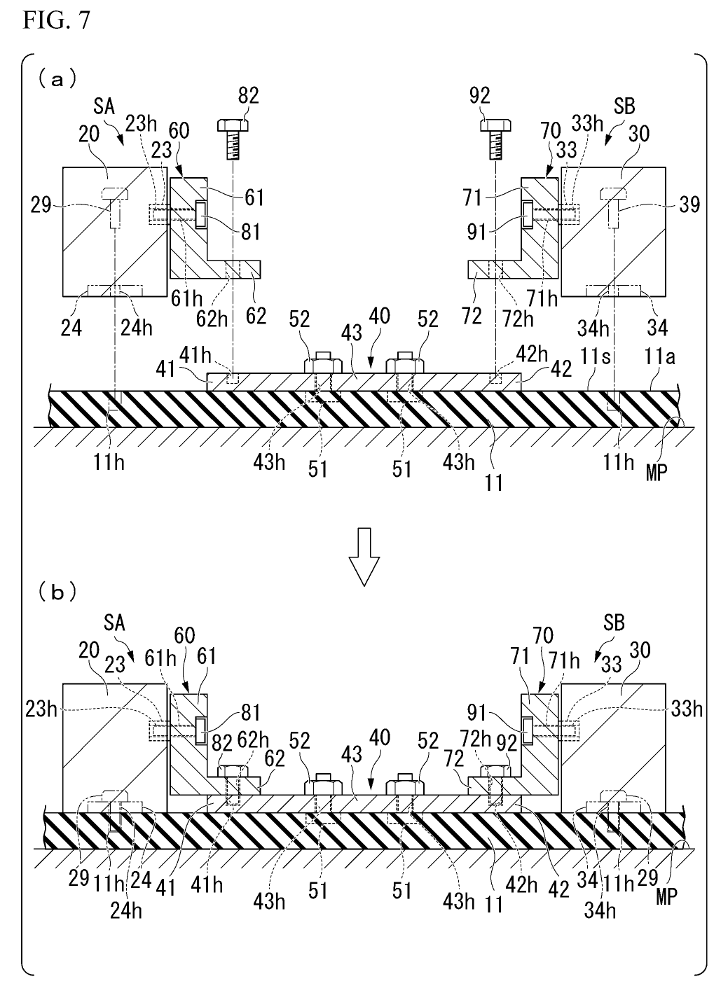

FIG. 7 illustrates a third step. The third step is performed after the first step and the second step. In the third step, the first assembly SA is fixed to the first connection portion 41 of the bus bar 40 using the second fastening member 82. For example, the first metal component 60 included in the first assembly SA is fixed to the first connection portion 41 of the bus bar 40 using the second fastening member 82. As a result, the first electronic component 20 and the bus bar 40 are electrically connected.

The third step is performed, for example, as follows. First, the posture of the first assembly SA is rotated by 90 degrees from the first step. That is, a first posture (see FIG. 5) in which the attachment hole 23h and the first attachment hole 61h are directed in the vertical direction is changed to a second posture (see FIG. 7) in which the attachment hole 23h and the first attachment hole 61h are directed in a horizontal direction and the second attachment hole 62h of the first metal component 60 is directed in the vertical direction.

In the second posture, the second portion 62 of the first metal component 60 is placed on the first connection portion 41 of the bus bar 40. The second attachment hole 62h of the first metal component 60 and the attachment hole 41h of the first connection portion 41 of the bus bar 40 are aligned.

Next, the second fastening member 82 is inserted into the second attachment hole 62h of the first metal component 60 in the vertical direction. The second fastening member 82 passed through the second attachment hole 62h of the first metal component 60 is engaged with the attachment hole 41h of the first connection portion 41 of the bus bar 40. As a result, the first metal component 60 is fixed to the first connection portion 41 of the bus bar 40. That is, the first assembly SA is fixed to the first connection portion 41 of the bus bar 40. As a result, the first electronic component 20 and the first connection portion 41 of the bus bar 40 are electrically connected. In the present embodiment, the direction in which the bus bar 40 is fixed to the base member 11 coincides with the direction in which the first assembly SA is fixed to the bus bar 40.

In the third step, the attachment portion 24 of the first electronic component 20 may be fixed to the base member 11 using the fastening member 29. This work is performed as follows, for example. First, the attachment hole 24h of the attachment portion 24 of the first electronic component 20 and the attachment hole 11h of the base member 11 are aligned. Next, the fastening member 29 is inserted into the attachment hole 24h of the first electronic component 20 in the vertical direction. The fastening member 29 passed through the attachment hole 24h of the first electronic component 20 is engaged with the attachment hole 11h of the base member 11. As a result, the first electronic component 20 is fixed to the base member 11. The work of fixing the first electronic component 20 to the base member 11 using the fastening member 29 may be performed before or after the work of fixing the first metal component 60 to the bus bar 40 using the second fastening member 82. In the present embodiment, the direction in which the bus bar 40 is fixed to the base member 11, the direction in which the first assembly SA is fixed to the bus bar 40, and the direction in which the first electronic component 20 is fixed to the base member 11 coincide with each other.

Similarly, the posture of the second assembly SB is rotated by 90 degrees from the first step. That is, a first posture (see FIG. 5) in which the attachment hole 33h and the first attachment hole 71h are directed in the vertical direction is changed to a second posture (see FIG. 7) in which the attachment hole 33h and the first attachment hole 71h are directed in the horizontal direction and the second attachment hole 72h of the second metal component 70 is directed in the vertical direction.

In the second posture, the second portion 72 of the second metal component 70 is placed on the second connection portion 42 of the bus bar 40. The second attachment hole 72h of the second metal component 70 and the attachment hole 42h of the second connection portion 42 of the bus bar 40 are aligned.

Next, the second fastening member 92 is inserted into the second attachment hole 72h of the second metal component 70 in the vertical direction. The second fastening member 92 passed through the second attachment hole 72h of the second metal component 70 is engaged with the attachment hole 42h of the second connection portion 42 of the bus bar 40. As a result, the second metal component 70 is fixed to the second connection portion 42 of the bus bar 40. That is, the second assembly SB is fixed to the second connection portion 42 of the bus bar 40. As a result, the second electronic component 30 and the second connection portion 42 of the bus bar 40 are electrically connected. In the present embodiment, the direction in which the bus bar 40 is fixed to the base member 11 coincides with the direction in which the second assembly SB is fixed to the bus bar 40.

In the third step, the attachment portion 34 of the second electronic component 30 may be fixed to the base member 11 using the fastening member 39. This work is performed as follows, for example. First, the attachment hole 34h of the attachment portion 34 of the second electronic component 30 and the attachment hole 11h of the base member 11 are aligned. Next, the fastening member 39 is inserted into the attachment hole 34h of the second electronic component 30 in the vertical direction. The fastening member 39 passed through the attachment hole 34h of the second electronic component 30 is engaged with the attachment hole 11h of the base member 11. As a result, the second electronic component 30 is fixed to the base member 11. The work of fixing the second electronic component 30 to the base member 11 using the fastening member 39 may be performed before or after the work of fixing the second metal component 70 to the bus bar 40 using the second fastening member 92. In the present embodiment, the direction in which the bus bar 40 is fixed to the base member 11, the direction in which the second assembly SB is fixed to the bus bar 40, and the direction in which the second electronic component 30 is fixed to the base member 11 coincide with each other.

### A3. Operation of Invention

Next, an operation of the electrical connection unit 1 in the invention will be described.

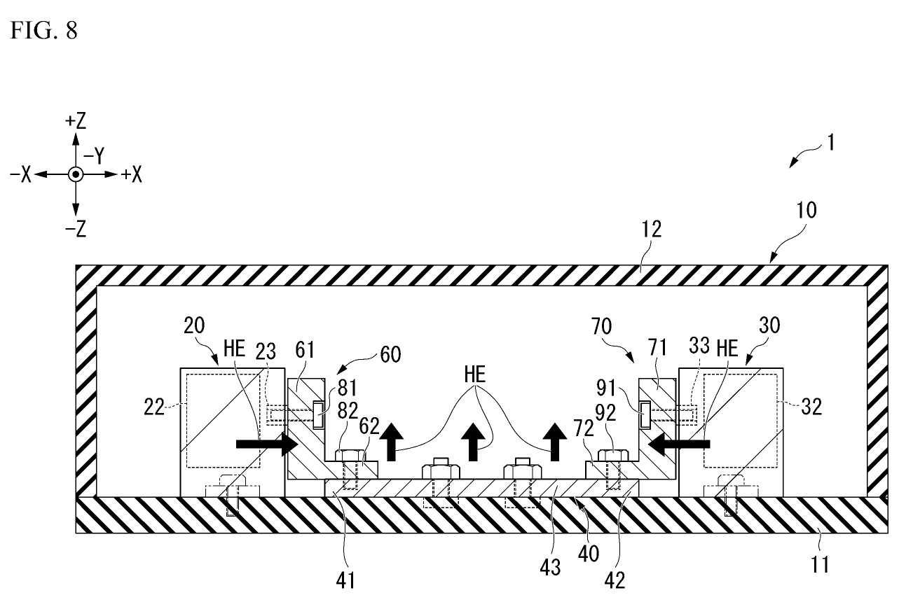

FIG. 8 is a cross-sectional view for describing the operation of the electrical connection unit 1.

When the first electronic component 20 is energized, the body portion 22 of the first electronic component 20 generates heat, and the terminal portion 23 connected to the body portion 22 becomes hot. Some of the heat (indicated by an arrow HE in FIG. 8) of the terminal portion 23 is transferred to the metal component 60. Some of the heat transferred to the metal component 60 is dissipated from the metal component 60 to the inside of the housing 10. Another some of the heat transferred to the metal component 60 is transferred from the metal component 60 to the bus bar 40. Some of the heat transferred to the bus bar 40 is dissipated from the bus bar 40 to the inside of the housing 10.

Here, when a short-term large current flows through the first electronic component 20 and the body portion 22 of the first electronic component 20 generates heat, the terminal portion 23 connected to the body portion 22 will have heat. In the present embodiment, the metal component 60 having a larger heat capacity per unit length than the bus bar 40 is present adjacent to the terminal portion 23. Therefore, some of the heat of the terminal portion 23 is stored (absorbed) by the metal component 60. As a result, even when a short-term large current flows through the first electronic component 20, it is possible to suppress excessive heat from moving to the bus bar 40 and the other electronic component 30. The operation of the invention similarly applies to the metal component 70.

### A4. Advantages

### A4.1 Advantages of Heat Storage Component (Heat Absorbing Component)

In the present embodiment, the electrical connection unit 1 includes the bus bar 40 and the first metal component 60. At least a part of the bus bar 40 has a plate shape. The first metal component 60 is disposed between the bus bar 40 and the first electronic component 20. The first metal component 60 electrically connects the bus bar 40 and the first electronic component 20. The thickness of at least a part of the first metal component 60 is larger than the plate thickness T3 of the bus bar 40.

According to such a constitution, the first metal component 60 has a larger heat capacity per unit length than that of the bus bar 40. Therefore, even when a short-term large current flows through the first electronic component 20 and the first electronic component 20 generates heat, some of the heat generated by the first electronic component 20 is stored by the metal component 60. As a result, it is possible to suppress a temperature change inside the electrical connection unit 1. As a result, the thermal characteristics of the electrical connection unit 1 can be improved.

In the present embodiment, the first metal component 60 is connected to the terminal portion 23 of the first electronic component 20 in the X direction using the first fastening member 81. According to such a constitution, it is possible to store some of the heat generated by the first electronic component 20 using the metal component 60 firmly fixed to the terminal portion 23 of the first electronic component 20 using the first fastening member 81. As a result, it is possible to further improve the thermal characteristics of the electrical connection unit 1.

In the present embodiment, the first metal component 60 is connected to the terminal portion 23 of the first electronic component 20 in the X direction. The thickness T1 of at least a part of the first metal component 60 in the X direction is larger than the plate thickness T3 of the bus bar 40. According to such a constitution, a metal portion having a large heat capacity is disposed near the terminal portion 23 which is likely to be hot in the first electronic component 20, and heat is more likely to be transferred from the terminal portion 23 to the first metal component 60. As a result, it is possible to further improve the thermal characteristics of the electrical connection unit 1.

In the present embodiment, the first metal component 60 has the first portion 61 connected to the terminal portion 23 of the first electronic component 20 in the X direction, and the second portion 62 protruding from the first portion 61 and connected to the bus bar 40 in the Z direction. According to such a constitution, the direction in which the bus bar 40 is fixed to the base member 11 and the direction in which the first metal component 60 is fixed to the bus bar 40 can be made to coincide with each other. Therefore, the assemblability of the electrical connection unit 1 can be improved.

In the present embodiment, the thickness T1 of the first portion 61 of the first metal component 60 in the X direction is larger than the thickness T2 of the second portion 62 of the first metal component 60 in the Z direction. According to such a constitution, a larger heat capacity can be secured by the first portion 61 of the first metal component 60. As a result, it is possible to further improve the thermal characteristics of the electrical connection unit 1.

In the present embodiment, the bus bar 40 includes the first connection portion 41 disposed along the base member 11. The first metal component 60 has the first portion 61 connected to the terminal portion 23 of the first electronic component 20 in the standing posture with respect to the base member 11, and the second portion 62 connected to the first connection portion 41 of the bus bar 40. According to such a constitution, the first portion 61 can be easily formed larger, and the heat capacity of the first portion 61 can be easily secured. According to the above constitution, the bus bar 40 having the first connection portion 41 disposed along the base member 11 can be adopted. As a result, the shape of the bus bar 40 can be simplified. As a result, it is possible to reduce the cost of the electrical connection unit 1.

### A4.2 Advantages of Connection Member

In the present embodiment, when the first metal component 60 is fixed to the terminal portion 23 of the first electronic component 20 using the first fastening member 81, the first assembly SA in which the first electronic component 20 and the first metal component 60 are integrated is formed. Then, after the first assembly SA is formed, the first metal component 60 included in the first assembly SA is fixed to the bus bar 40 using the second fastening member 82, and thus the first electronic component 20 and the bus bar 40 are electrically connected. According to such a constitution, the first assembly SA in which the first electronic component 20 and the first metal component 60 are integrated is formed first. Therefore, the assemblability of the first electronic component 20 and the first metal component 60 to the bus bar 40 can be enhanced. Thus, the assemblability of the electrical connection unit 1 can be improved.

In addition, according to the above constitution, since the first metal component 60 can form a standing energization part in the housing 10, it is easy to adopt the bus bar 40 having a simple shape (for example, the plate-shaped bus bar 40 having few bent portions). Therefore, the assemblability of the first electronic component 20 and the first metal component 60 to the bus bar 40 can be enhanced.

In addition, according to the above constitution, since the first metal component 60 can form a standing energization part in the housing 10, so that the bent portion of the bus bar 40 can be reduced. Here, the bus bar 40 corresponding to a large current has a large cross-sectional area in order to suppress self-heating of the bus bar, and the bending processing cost tends to increase. Therefore, if the number of bent portions of the bus bar 40 can be reduced, the cost of the electrical connection unit 1 can be reduced.

In the present embodiment, the width of the first metal component 60 in the longitudinal direction of the first electronic component 20 is smaller than the width of the first electronic component 20 in the longitudinal direction. According to such a constitution, when the first assembly SA is formed by fixing the first electronic component 20 and the first metal component 60, since the first assembly SA is relatively small, it is possible to enhance the assemblability with respect to the bus bar 40 previously integrated with the base member 11. As a result, the assemblability of the electrical connection unit 1 can be further improved.

In the present embodiment, fixing the first assembly SA to the bus bar 40 using the second fastening member 82 is performed in a state where the bus bar 40 is fixed to the base member 11 having insulating properties. According to such a constitution, since the bus bar 40 is previously fixed to the base member 11, the assemblability of the first assembly SA with respect to the base member 11 and the bus bar 40 can be enhanced. As a result, the assemblability of the electrical connection unit 1 can be further improved.

In the present embodiment, fixing the first metal component 60 to the terminal portion 23 of the first electronic component 20 using the first fastening member 81 is performed in a state where the first metal component 60 is in the first posture. Fixing the first metal component 60 included in the first assembly SA to the bus bar 40 using the second fastening member 82 is performed in a state where the first metal component 60 is in the second posture different from the first posture. According to such a constitution, by changing the posture of the first metal component 60, the fixation using the first fastening member 81 and the fixation using the second fastening member 82 can be performed in more appropriate postures. As a result, the assemblability of the electrical connection unit 1 can be further improved.

In the present embodiment, the first metal component 60 has the first attachment hole 61h into which the first fastening member 81 is inserted and the second attachment hole 62h into which the second fastening member 82 is inserted. The first posture is a posture in which the first attachment hole 61h is directed in the first attachment direction (for example, the vertical direction). The second posture is a posture in which the first attachment hole 61h is directed in a direction different from the first attachment direction and the second attachment hole 62h is directed in the first attachment direction (Z direction). According to such a constitution, the direction in which the first electronic component 20 and the first metal component 60 are fixed using the first fastening member 81 can be made to coincide with the direction in which the first metal component 60 and the bus bar 40 are fixed using the second fastening member 82. As a result, workability can be enhanced, and the assemblability of the electrical connection unit 1 can be further improved.

### A5. Modified Examples

Next, several modified examples will be described. Note that a constitution other than that described below in each modified example is the same as the constitution of the first embodiment.

### A5.1 First Modified example

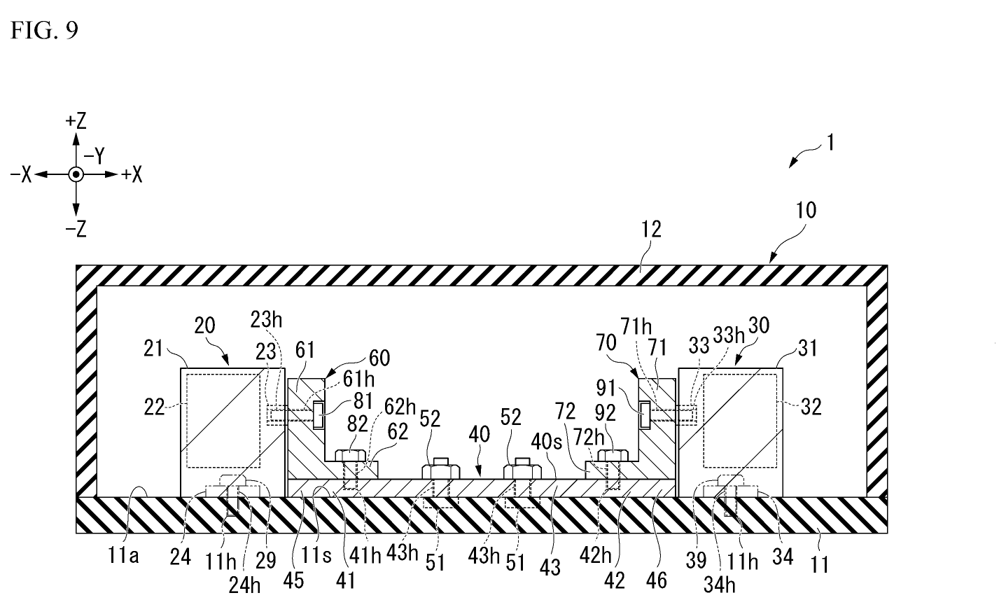

FIG. 9 is a cross-sectional view illustrating an electrical connection unit 1 of a first modified example. In the first modified example, the bus bar 40 includes an extension portion 45 and an extension portion 46. The extension portion 45 extends in the -X direction beyond the first connection portion 41. The extension portion 45 overlaps the first portion 61 of the first metal component 60 when viewed in the Z direction. On the other hand, the extension portion 46 extends in the +X direction beyond the second connection portion 42. The extension portion 46 overlaps the first portion 71 of the second metal component 70 when viewed in the Z direction. The extension portion 45 and the extension portion 46 have a plate shape in the X direction and the Y direction.

According to such a constitution, the heat capacity and the heat dissipation area of the bus bar 40 are enlarged by the extension portions 45 and 46. As a result, a temperature change inside the electrical connection unit 1 can be further suppressed, and the heat dissipation properties of the electrical connection unit 1 can be improved.

### A5.2 Second Modified example

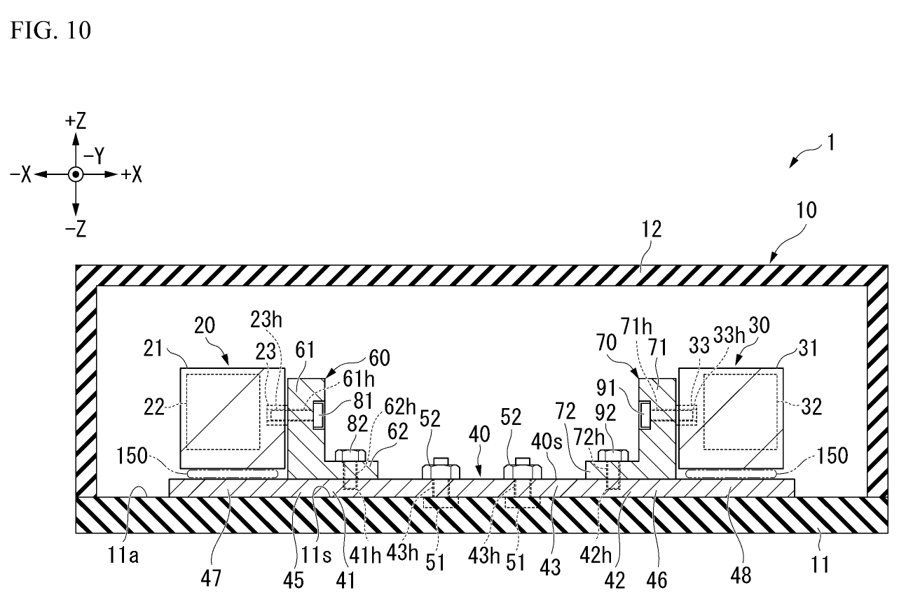

FIG. 10 is a cross-sectional view illustrating an electrical connection unit 1 of a second modified example. In the second modified example, the bus bar 40 includes an extension portion 47 and an extension portion 48. The extension portion 47 extends in the -X direction beyond the extension portion 45. The extension portion 47 overlaps the first electronic component 20 when viewed in the Z direction. The extension portion 47 extends in the X direction between the first electronic component 20 and the base member 11. On the other hand, the extension portion 48 extends in the +X direction beyond the extension portion 46. The extension portion 48 overlaps the second electronic component 30 when viewed in the Z direction. The extension portion 48 extends in the X direction between the second electronic component 30 and the base member 11. The extension portion 47 and the extension portion 48 have a plate shape in the X direction and the Y direction.

According to such a constitution, the heat capacity and the heat dissipation area of the bus bar 40 are enlarged by the extension portion 47 or the extension portion 48. Here, for example, by providing the first metal component 60, it is not necessary to bend the bus bar 40 in accordance with the first electronic component 20. Therefore, a part of the bus bar 40 can be extended, for example, between the first electronic component 20 and the base member 11. As a result, a rapid temperature change inside the electrical connection unit 1 can be further suppressed, and the heat dissipation properties of the electrical connection unit 1 can be further improved.

Note that a heat transfer member 150 may be provided between the first electronic component 20 and the extension portion 47. The heat transfer member 150 transfers some of the heat generated by the first electronic component 20 to the extension portion 47. Some of the heat transferred to the extension portion 47 is dissipated through the base member 11. Similarly, the heat transfer member 150 may be provided between the second electronic component 30 and the extension portion 48. Some of the heat transferred to the extension portion 48 is dissipated through the base member 11. The heat transfer member 150 transfers some of the heat generated by the second electronic component 30 to the extension portion 48. The heat transfer member 150 is, for example, a resin member having excellent thermal conductivity. Thus, the heat dissipation properties of the electrical connection unit 1 can be further improved.

### A5.3 Third Modified example

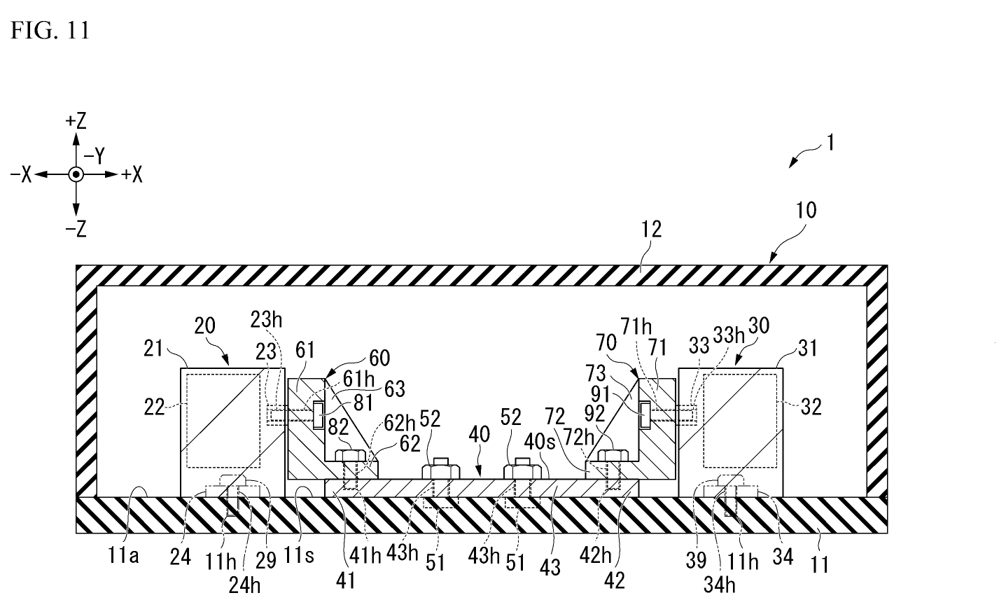

FIG. 11 is a cross-sectional view illustrating an electrical connection unit 1 of a third modified example. In the third modified example, the first metal component 60 includes a third portion 63 in addition to the first portion 61 and the second portion 62. The second metal component 70 includes a third portion 73 in addition to the first portion 71 and the second portion 72. The third portion 73 has the same shape as the third portion 63 of the first metal component 60. Therefore, the third portion 63 of the first metal component 60 will be described below.

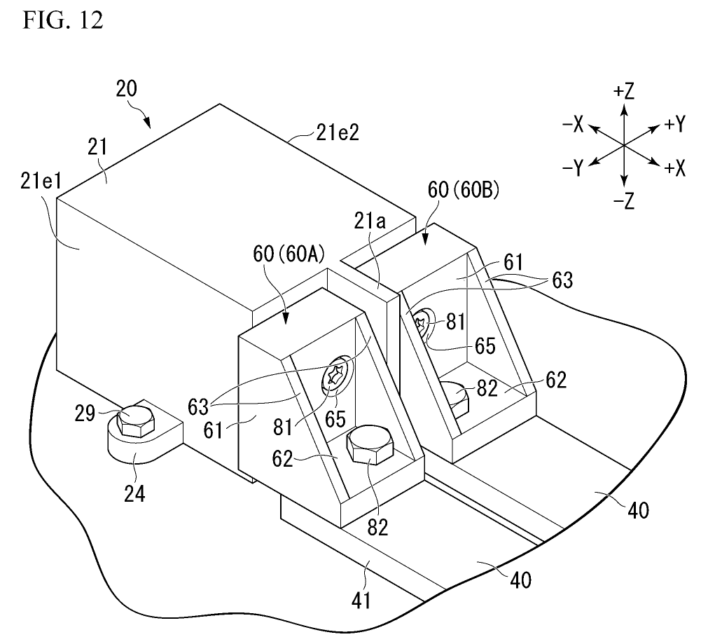

FIG. 12 is a perspective view illustrating a part of the electrical connection unit 1 of the third modified example. The third portion 63 is a standing wall (side wall) standing laterally of the fastening members 81 and 82. For example, the first metal component 60 has the third portions 63 at both end portions in the Y direction of the first metal component 60. The third portion 63 is a wall in the X direction and the Y direction. The third portion 63 is connected to the first portion 61 and is also connected to the second portion 62. For example, the third portion 63 extends obliquely so as to expand in the +X direction while extending in the -Z direction.

According to such a constitution, the heat capacity and the heat dissipation area of the first metal component 60 are enlarged by the third portion 63. As a result, a temperature change inside the electrical connection unit 1 can be further suppressed, and the heat dissipation properties of the electrical connection unit 1 can be further improved. The third portion 63 may be provided at one end portion in the Y direction of the first metal component 60 instead of being provided at both end portions in the Y direction of the first metal component 60.

### Second Embodiment

Next, a second embodiment will be described. The second embodiment is different from the first embodiment in that the first fastening member 81 is attached in the Z direction. The constitution other than that described below is the same as that of the first embodiment. In the second embodiment, the Z direction is an example of a “first direction”. The X direction is an example of a “second direction”.

### B1. Constitution of Electrical Connection Unit

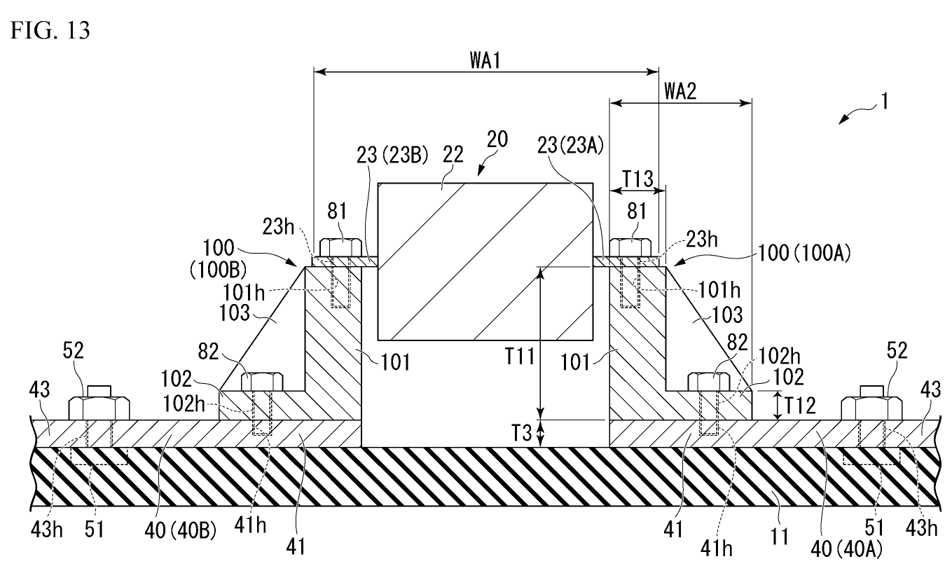

FIG. 13 is a cross-sectional view illustrating a part of the electrical connection unit 1 of the second embodiment. The electrical connection unit 1 includes, for example, the electronic component 20, the plurality of bus bars 40, and a plurality of metal components 100.

### B1.1 Electronic Component

The electronic component 20 includes, for example, the body portion 22 and the plurality of terminal portions 23 (first terminal portion 23A and second terminal portion 23B). The body portion 22 has, for example, a columnar shape whose axis is in the X direction. The plurality of terminal portions 23 are provided separately on both end sides in the X direction of the body portion 22. For example, the first terminal portion 23A extends in the +X direction from an end portion of the body portion 22 in the +X direction. The second terminal portion 23B extends in the -X direction from an end portion of the body portion 22 in the -X direction. Each of the first terminal portion 23A and the second terminal portion 23B has the attachment hole 23h. The attachment hole 23h is open in the Z direction.

### B1.2 Bus Bar

The plurality of bus bars 40 are disposed separately in the X direction of the electronic component 20. The plurality of bus bars 40 include a first bus bar 40A and a second bus bar 40B. The first bus bar 40A is disposed on the +X direction side of the electronic component 20. The second bus bar 40B is disposed on the -X direction side of the electronic component 20.

### B1.3 Metal Component

The plurality of metal components 100 are heat storage members (heat absorbing members) that increase the heat capacity of the energization path of the electrical connection unit 1. The plurality of metal components 100 store (absorb) at least some of heat generated by the electronic component 20, for example. Alternatively/additionally, the plurality of metal components 100 may store (absorb) at least some of heat generated by the bus bar 40 due to energization. The plurality of metal components 100 include a first metal component 100A and a second metal component 100B.

### B1.3.1 First Metal Component

The first metal component 100A is disposed between the electronic component 20 and the first bus bar 40A. The first metal component 100A electrically connects the terminal portion 23A of the electronic component 20 and the first connection portion 41 of the first bus bar 40A. The first metal component 100A includes, for example, a first portion 101, a second portion 102, and a third portion 103.

### First Portion

The first portion 101 is a portion connected to the terminal portion 23A of the electronic component 20. The first portion 101 is a rectangular parallelepiped metal portion. The first portion 101 extends in the Z direction. The first portion 101 is adjacent to at least a part of the body portion 22 of the electronic component 20 in the X direction. The first portion 101 faces the terminal portion 23A of the electronic component 20 from the +Z direction side. The terminal portion 23A of the electronic component 20 is connected to the first portion 101 in the Z direction.

In the present embodiment, the first portion 101 has a first attachment hole 101h with which the first fastening member 81 (for example, a screw) is engaged. The first attachment hole 101h is open in the Z direction. The first fastening member 81 passed through the attachment hole 23h of the terminal portion 23A of the electronic component 20 is engaged with the first attachment hole 101h of the first portion 101, thereby physically and electrically connecting the first portion 61 to the terminal portion 23A of the electronic component 20.

### Second Portion

The second portion 102 is a portion connected to the first connection portion 41 of the first bus bar 40A. The second portion 102 protrudes in the +X direction from an end portion of the first portion 101 on the -Z direction side. The second portion 102 is a plate portion in the X direction and the Y direction. The second portion 102 extends in the X direction along the first connection portion 41 of the first bus bar 40A. In the present embodiment, the first portion 101 and the second portion 102 form an L-shaped metal component.

The second portion 102 is adjacent to the first connection portion 41 of the first bus bar 40A in the Z direction. The second portion 102 faces the first connection portion 41 of the first bus bar 40A from the +Z direction side. The second portion 102 is connected to the first connection portion 41 of the first bus bar 40A in the Z direction.

In the present embodiment, the second portion 102 has a second attachment hole 102h through which the second fastening member 82 (for example, a screw) passes. The second attachment hole 102h is open in the Z direction. The second fastening member 82 passed through the second attachment hole 102h is engaged with the attachment hole 41h of the first connection portion 41 of the first bus bar 40A, thereby physically and electrically connecting the second portion 102 to the first connection portion 41 of the bus bar 40.

### Third Portion

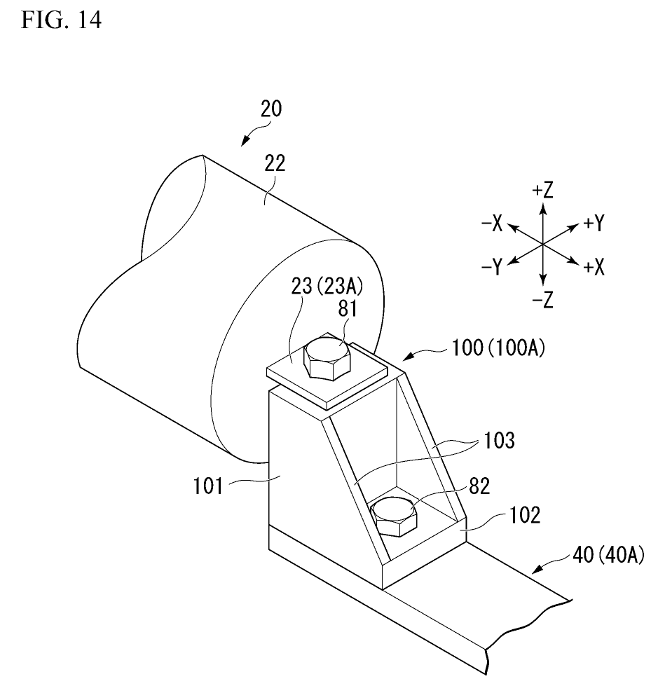

FIG. 14 is a perspective view illustrating a part of the electrical connection unit 1 of the second embodiment. The third portion 103 is a standing wall (side wall) standing laterally of the second fastening member 82. For example, the first metal component 100A has the third portions 103 at both end portions of the first metal component 100A in the Y direction. The third portion 103 is a wall in the X direction and the Y direction. The third portion 103 is connected to the first portion 101 and is also connected to the second portion 102. For example, the third portion 103 extends obliquely so as to expand in the +X direction while extending in the -Z direction.

### Shape of First Metal Component

Referring back to FIG. 13, the shape of the first metal component 100A will be described. In the present embodiment, a thickness of at least a part of the first metal component 100A is larger than a plate thickness T3 of the first bus bar 40A. For example, a thickness T11 of at least a part of the first metal component 100A in the Z direction is larger than the plate thickness T3 of the first bus bar 40A. In the present embodiment, the thickness T11 of the first portion 101 of the first metal component 100A in the Z direction is larger than a thickness T12 of the second portion 102 of the first metal component 100A in the Z direction. From another viewpoint, a thickness T13 of the first portion 101 of the first metal component 100A in the X direction is larger than the plate thickness T3 of the first bus bar 40A. From another viewpoint, the thickness T12 of the second portion 102 of the first metal component 100A in the Z direction may be larger than the plate thickness T3 of the bus bar 40.

In the present embodiment, the longitudinal direction of the electronic component 20 is the X direction. The width WA2 of the first metal component 100A in the X direction is, for example, smaller than the width WA1 of the electronic component 20 in the X direction. When the longitudinal direction of the first electronic component 20 is the Y direction, the width of the first metal component 100A in the Y direction is smaller than the width of the electronic component 20 in the Y direction, for example.

### B1.3.2 Second Metal Component

Next, the second metal component 100B will be described. The second metal component 100B is disposed between the electronic component 20 and the second bus bar 40B. The second metal component 100B electrically connects a terminal portion 23B of the electronic component 20 and the first connection portion 41 of the second bus bar 40B. Similarly to the first metal component 100A, the second metal component 100B includes a first portion 101, a second portion 102, and a third portion 103.

Details of the second metal component 100B are, for example, similar to those of the first metal component 100A. For this reason, in the description of the second metal component 100B, “terminal portion 23A”, “first bus bar 40A”, and “+X direction” in the description of the above-described first metal component 100A may be replaced with “terminal portion 23B”, “second bus bar 40B”, and “-X direction”, respectively.

### B2. Method for Manufacturing Electrical Connection Unit

Next, a method for manufacturing the electrical connection unit 1 of the second embodiment will be described.

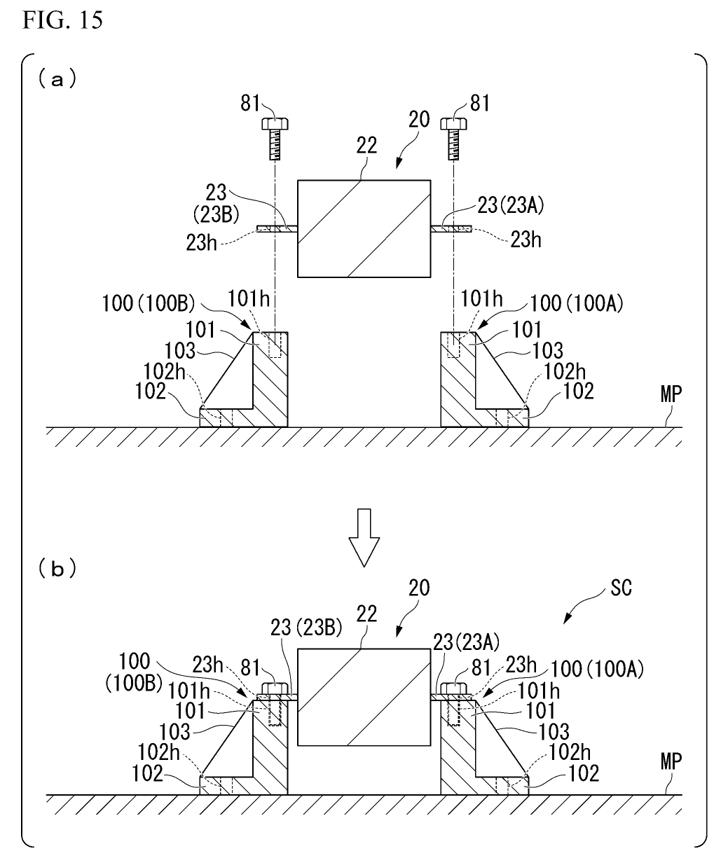

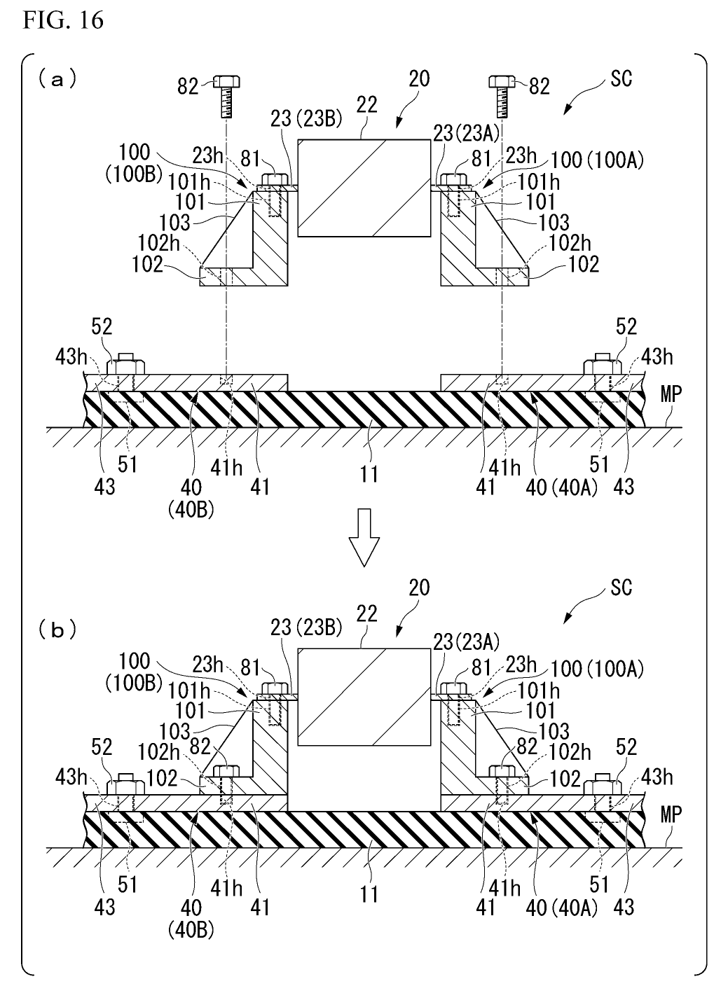

FIGS. 15 and 16 are cross-sectional views for describing the method for manufacturing the electrical connection unit 1 of the second embodiment.

### First Step

FIG. 15 illustrates a first step. In the first step, the terminal portion 23A of the electronic component 20 is fixed to the first metal component 100A using the fastening member 81, and the terminal portion 23B of the electronic component 20 is fixed to the second metal component 100B using the fastening member 81. As a result, an assembly SC in which the electronic component 20, the first metal component 100A, and the second metal component 100B are integrated is formed.

The first step is performed, for example, as follows. First, the first metal component 100A is placed on the placement table MP in a posture in which the first attachment hole 101h of the first metal component 100A is directed in the vertical direction. Next, in a first posture in which the attachment hole 23h of the terminal portion 23A of the electronic component 20 is directed in the vertical direction, the terminal portion 23A of the electronic component 20 is placed on the first portion 101 of the first metal component 100A. Then, the attachment hole 23h of the electronic component 20 and the first attachment hole 101h of the first metal component 100A are aligned.

Next, the fastening member 81 is inserted into the attachment hole 23h of the electronic component 20 in the vertical direction. Then, the fastening member 81 passed through the attachment hole 23h of the electronic component 20 is engaged with the first attachment hole 101h of the first metal component 100A. As a result, the first metal component 100A is fixed to the electronic component 20. According to the same procedure, the second terminal portion 23B of the electronic component 20 is fixed to the second metal component 100B. As a result, an assembly SC in which the electronic component 20, the first metal component 100A, and the second metal component 100B are integrated is formed.

### Second Step

In a second step, the first bus bar 40A and the second bus bar 40B are fixed to the base member 11. Since the second step is the same as that of the first embodiment, redundant description will be omitted.

### Third Step

FIG. 16 illustrates a third step. The third step is performed after the first step and the second step. In the third step, the assembly SC is fixed to the first bus bar 40A and the second bus bar 40B using the second fastening member 82. For example, the second fastening member 82 is attached in the vertical direction, and the first metal component 100A of the assembly SC is fixed to the first connection portion 41 of the first bus bar 40A. As a result, the electronic component 20 and the first bus bar 40A are electrically connected. Similarly, the second fastening member 82 is attached in the vertical direction, and the second metal component 100B of the assembly SC is fixed to the first connection portion 41 of the second bus bar 40B. As a result, the electronic component 20 and the second bus bar 40B are electrically connected.

### B3. Advantages

In the present embodiment, the first metal component 100A includes the first portion 101 and the second portion 102. The first portion 101 is connected to the terminal portion 23A of the electronic component 20 in the Z direction. The second portion 102 protrudes from the first portion 101 in the X direction, is adjacent to the first bus bar 40A in the Z direction, and is connected to the first bus bar 40A. The thickness T11 of the first portion 101 in the Z direction is larger than the plate thickness T3 of the first bus bar 40A. According to such a constitution, it is possible to suppress occurrence of a rapid temperature change inside the electrical connection unit 1. As a result, the thermal characteristics of the electrical connection unit 1 can be improved.

In the present embodiment, the first fastening member 81 fixes the terminal portion 23A of the electronic component 20 to the first metal component 100A in the Z direction. The second fastening member 82 fixes the first metal component 100A to the first bus bar 40A in the Z direction. According to such a constitution, the direction in which the electronic component 20 and the first metal component 100A are fixed using the first fastening member 81 can be made to coincide with the direction in which the first metal component 100A and the first bus bar 40A are fixed using the second fastening member 82. Thus, workability is improved, and the assemblability of the electrical connection unit 1 can be improved.

### Third Embodiment

Next, a third embodiment will be described. The third embodiment is different from the first embodiment in that the connection target component is a bus bar 201. The constitution other than that described below is the same as that of the second embodiment. In the third embodiment, the Z direction is an example of a “first direction”.

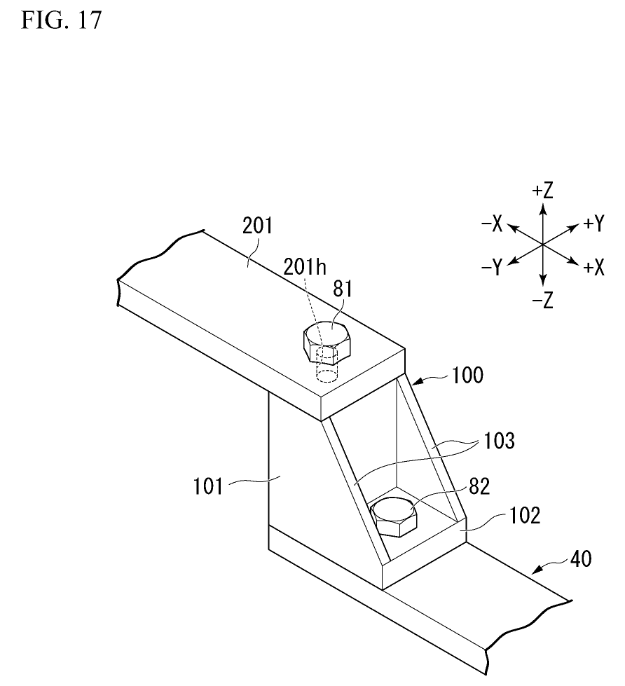

FIG. 17 is a perspective view illustrating a part of an electrical connection unit 1 of the third embodiment. In the present embodiment, the electrical connection unit 1 includes the bus bar 40, the metal component 100, and the bus bar 201. The bus bar 201 is an example of a “connection target component”.

The metal component 100 is disposed between the bus bar 201 and the bus bar 40. The bus bar 201 faces the first portion 101 of the metal component 100 from the +Z direction side. The bus bar 201 has an attachment hole 201h. The attachment hole 201h is open in the Z direction. The attachment hole 201h of the bus bar 201 is disposed corresponding to the attachment hole 101h of the metal component 100. The first fastening member 81 passed through the attachment hole 201h of the bus bar 201 in the vertical direction is engaged with the attachment hole 101h of the metal component 100, thereby fixing the bus bar 201 and the metal component 100 together. The metal component 100 electrically connects the bus bar 201 and the bus bar 40.

According to such a constitution, some of heat generated at the bus bar 201 or the connection destination of the bus bar 201 can be stored (absorbed) by the metal component 100. As a result, the thermal characteristics of the electrical connection unit 1 can be improved.

Several embodiments and modified examples have been described above. However, the embodiments and the modified examples are not limited to the examples described above. For example, two or more embodiments or modified examples described above may be implemented in combination with each other. In addition, the embodiments and modified examples described above are merely examples. The electrical connection unit 1 is not limited to the constitution including all the dimensional relationships described above, and may have a constitution including only a part of the dimensional relationships described above. In addition, when attention is paid to the functions of the metal components 60 and 70 as connection members (functions for improving assemblability), the metal components 60 and 70 are not necessarily limited to members having heat storage properties. For example, an L-shaped thin metal plate (metal component) may be used instead of the metal components 60 and 70.

### Industrial Applicability

According to the present disclosure, thermal characteristics of the electrical connection unit can be improved.

### Reference Signs List

1 Electrical connection unit

10 Housing

11 Base member

12 Cover member

20 First electronic component

23, 23A, 23B Terminal portion

30 Second electronic component

33, 33A, 33B Terminal portion

40 Bus bar

60 First metal component

61 First portion

61h First attachment hole

62 Second portion

62h Second attachment hole

70 Second metal component

71 First portion

71h First attachment hole

72 Second portion

72h Second attachment hole

81 First fastening member

82 Second fastening member

91 First fastening member

92 Second fastening member

100 Metal component

100A First metal component

101 First portion

102 Second portion

100B Second metal component

SA First assembly

SB Second assembly

1. An electrical connection unit comprising:
a first bus bar at least a part of which has a plate shape; and
a metal component which is disposed between the first bus bar and a connection target component that is an electronic component or a second bus bar and electrically connects the first bus bar and the connection target component, and at least a part of which has a thickness larger than a plate thickness of the first bus bar.

2. The electrical connection unit according to claim 1,
wherein the connection target component is the electronic component,
wherein the electronic component includes a terminal portion, and
wherein the metal component is connected to the terminal portion using a fastening member.

3. The electrical connection unit according to claim 1,
wherein the connection target component is the electronic component,
wherein the electronic component includes a terminal portion, and
wherein the metal component is connected to the terminal portion in a first direction, and at least a part of the metal component has a thickness in the first direction larger than the plate thickness of the first bus bar.

4. The electrical connection unit according to claim 3, wherein
the metal component has a first portion connected to the terminal portion in the first direction and a second portion protruding from the first portion and connected to the first bus bar in a second direction intersecting the first direction.

5. The electrical connection unit according to claim 4, wherein
a thickness of the first portion in the first direction is larger than a thickness of the second portion in the second direction.

6. The electrical connection unit according to claim 3, further comprising
a support to which the first bus bar is attached,
wherein the first bus bar includes a plate-shaped connection portion disposed along the support, and
wherein the metal component includes a first portion connected to the terminal portion in a standing posture with respect to the support, and a second portion connected to the connection portion of the first bus bar.

7. The electrical connection unit according to claim 1,
wherein the connection target component is the electronic component,
wherein the electronic component includes a terminal portion, and
wherein the metal component includes a first portion connected to the terminal portion in a first direction, and a second portion protruding from the first portion in a second direction intersecting the first direction and connected to the first bus bar in the first direction.

8. The electrical connection unit according to claim 7, wherein
a thickness of the first portion in the first direction is larger than a thickness of the second portion in the first direction.

9. The electrical connection unit according to claim 1, wherein
the connection target component is the second bus bar.

10. A metal component which is disposed between a first bus bar at least a part of which has a plate shape and a connection target component that is an electronic component or a second bus bar and electrically connects the first bus bar and the connection target component, and at least a part of which has a thickness larger than a plate thickness of the first bus bar.
